(19) United States
(12) Patent Application Publication
(10) Pub. No.: US 2007/0126112 A1
(43) Pub. Date: Jun. 7, 2007

(54) Metal core, package board, and fabricating method thereof

(75) Inventors: Seung-Hyun Cho, Seoul (KR); Dae-Hyun Park, Ulsan (KR); Young-Goo Kim, Busan (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/606,943

(22) Filed: Dec. 1, 2006

(30) Foreign Application Priority Data
Dec. 7, 2005 (KR) 10-2005-0118610

(51) Int. Cl. H01L 23/12; H01L 21/00

(52) U.S. Cl. 257/700; 438/121; 257/E23.174

(57) ABSTRACT

A metal core and a package board having the metal core are disclosed. A package board, which comprises a metal core having a plurality of protrusions formed in a lengthwise direction on its surface, an insulation layer stacked on the metal core, and an inner layer circuit formed on the insulation layer for signal connection between a chip and the exterior, has a greater surface area due to the protrusions, so that it is superior in terms of heat releasing and of adhesion to the insulation layer, and has superior mechanical properties with respect to warpage.

### CROSS-REFERENCE TO RELATED APPLICATIONS

This application claims the benefit of Korean Patent Application No. 2005-0118610 filed with the Korean Intellectual Property Office on Dec. 7, 2005, the disclosure of which is incorporated herein by reference in its entirety.

### BACKGROUND

1. Technical Field

The present invention relates to a metal core used in a circuit board, a package board having the metal core, and a fabricating method thereof.

2. Description of the Related Art

As electronic products are being made smaller and lighter, represented by the trends of smaller, thinner, higher-density, packaged, and portable products, so also is the multilayer printed circuit board undergoing a trend towards finer patterns and smaller and packaged products. Accordingly, along with changes in the raw materials for forming fine patterns on the multilayer printed circuit board and for improving reliability and design density, there is a change towards integrating the layer composition of circuits. Components are also undergoing a change from DIP (dual in-line package) types to SMT (surface mount technology) types, so that the mounting density is also being increased. Further, the development of portable electronic devices, as well as demands for more functionalities, Internet use, video clips, and high-capacity data transmission, etc., create a need for more complicated designs and higher levels of technology for the printed circuit board.

With such increases in the number and density of chips mounted on a printed circuit board, superior heat releasing properties are required of the printed circuit board for the heat generated by the chips. Also, with the increasing number of components mounted on the board, another requirement is that there be no warpage in the board.

### SUMMARY

The present invention aims to provide a metal core, a package board having the metal core, and a fabricating method thereof, which provide superior heat releasing properties and superior mechanical properties with respect to warpage.

Another object of the invention is to provide a metal core, a package board having the metal core, and a fabricating method thereof, which allow easy adhesion to an insulation layer.

One aspect of the invention provides a metal core comprising a plurality of protrusions formed in a lengthwise direction on its surface.

A metal core according to embodiments of the invention may include one or more of the following features. For example, the protrusions may be formed on both sides of the metal core. Also, the metal core may include any one of copper (Cu), aluminum (Al), titanium (Ti), zinc (Zn), and tantalum (Ta).

Another aspect of the invention provides a package board comprising a metal core having a plurality of protrusions formed in a lengthwise direction on its surface, an insulation layer stacked on the metal core, and an inner layer circuit formed on the insulation layer for signal connection between a chip and the exterior.

A package board according to embodiments of the invention may include one or more of the following features. For example, the insulation layer may be a resin coated on a resin-coated copper foil. The protrusions may be formed on both sides of the metal core, while the metal core may be formed including any one of copper (Cu), aluminum (Al), titanium (Ti), zinc (Zn), and tantalum (Ta).

Yet another aspect of the invention provides a method of fabricating a package board comprising (a) processing at least one surface of a metal plate to provide a metal core having protrusions formed in a lengthwise direction, (b) stacking at least one insulation layer on the metal core, and (c) forming an inner layer circuit and mounting a chip.

A method of fabricating a package board according to embodiments of the invention may include one or more of the following features. For example, in the operation (a) of processing at least one surface of a metal plate to provide a metal core having protrusions formed in a lengthwise direction, the metal core may be formed by press processing, and the protrusions may be formed on both sides of the metal plate. The metal plate may include any one of copper (Cu), aluminum (Al), titanium (Ti), zinc (Zn), and tantalum (Ta). Also, the insulation layer may be formed by stacking at least one resin-coated copper foil on the metal core.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a perspective view of a metal core according to an embodiment of the invention.

FIG. 2 is a cross-sectional view of the metal core across line I-I′ of FIG. 1.

FIG. 3 is a cross-sectional view of a package board according to an embodiment of the invention.

FIG. 4 is a cross-sectional view after resin-coated copper foils have been stacked on both sides of a metal core, in a method of fabricating a package board according to an embodiment of the invention.

FIG. 5 is a cross-sectional view after through-holes have been formed in the metal core illustrated in FIG. 4 having resin-coated copper foils stacked.

FIG. 6 is a cross-sectional view after plating has been performed to form plating layers on the metal core of FIG. 5 having resin-coated copper foils stacked.

FIG. 7 is a cross-sectional view after forming circuit patterns and selectively applying solder resist to form wire pads and ball pads on the metal core of FIG. 6 having resin-coated copper foils stacked.

FIG. 8 is a cross-sectional view after attaching a peelable coating on the resin-coated copper foil illustrated in FIG. 7 in a portion where a chip is to be mounted.

### DETAILED DESCRIPTION

Embodiments of the invention will be described below in more detail with reference to the accompanying drawings. In the description with reference to the accompanying drawings, those components are rendered the same reference number that are the same or are in correspondence regardless of the figure number, and redundant explanations are omitted.

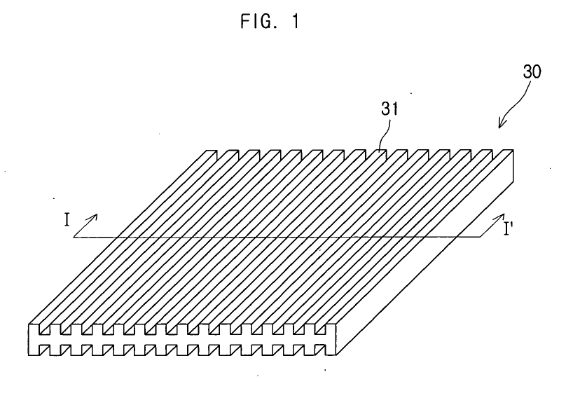

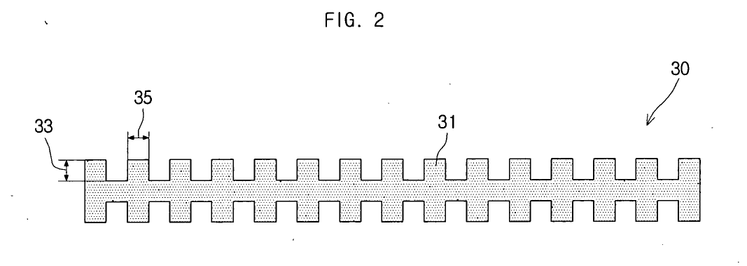

Detailed descriptions will now be provided, with reference to FIGS. 1 and 2, of a metal core 30 according to an embodiment of the invention.

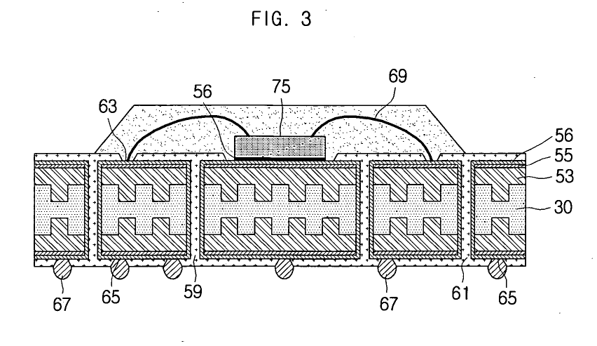

Referring to FIG. 1, a metal core 30 according to an embodiment of the invention has protrusions 31 formed in a lengthwise direction on both sides of a metal plate. The metal core 30, as illustrated in FIG. 3, is used as a substrate of a package board 50 to improve the board's heat-releasing properties and its mechanical properties with respect to warpage. The metal core 30 may be formed including any one of copper (Cu), aluminum (Al), titanium (Ti), zinc (Zn), and tantalum (Ta). Aluminum (Al) is a good electrical conductor, having a specific resistance 1.6 times that of copper, and is also a good heat conductor, to provide a superior heat-releasing effect when a chip is mounted. It is also a light metal, high in strength per mass, so that the mass and thickness of the overall board may be reduced.

The protrusions 31 are formed in a lengthwise direction of the metal core 30, and increase the surface area of the metal core 30 to improve the adhesion to an insulation layer (53 of FIG. 3). Furthermore, since the surface area is increased due to the protrusions 31, heat can be released more easily.

Referring to FIG. 2, the metal core 30 has a cross section in the form of 1-beams. In general, for the same cross-sectional area, the greater the area moment of inertia, the greater the bending strength. Thus, an I-beam has a greater bending strength than does a square beam of equal cross-sectional area. The height 33 and width 35 of a protrusion 31 may vary as necessary. Also, the protrusions 31 may obviously be modified to have any of a variety of cross sections, such as to have a quadrilateral or a cone shape.

While in FIGS. 1 and 2 the protrusions 31 are formed on both sides of the metal core 30, the protrusions 31 may also be formed on only one side of the metal core 30.

Detailed descriptions will now be provided, with reference to FIG. 3, of a package board according to an embodiment of the invention.

Referring to FIG. 3, a package board according to an embodiment of the invention uses as the substrate a metal core 30 having a plurality of protrusions 31. On each side of the metal core 30, an insulation layer 53 and a copper laminate 55 are stacked in order, while on the copper laminate 55 is formed a plating layer 56. Also, solder resist 61 is filled in through-holes 59 formed in the metal core 30, insulation layer 53, and copper laminate 55, while a chip 75 is connected by wires 69 to wire pads 63. The wire pads 63 are electrically connected by the plating layers 56 to solder balls 67.

Since the package board 50 according to the present embodiment uses a metal core 30 having a plurality of protrusions 31, it has superior mechanical properties with respect to warpage. Also, as the surface area is increased due to the plurality of protrusions 31, the heat generated by the chip 75 can readily be released, and there is superior adhesion to the insulation layer 53.

Detailed descriptions will now be provided for each component of a package board according to an embodiment of the invention.

The insulation layers 53 are formed by stacking insulation material such as epoxy resin, etc., on both sides of the metal core 30. The insulation layers 53 fill in the gaps between the protrusions 31 of the metal core 30, to be attached to the metal core 30. The copper laminates 55 are stacked on the insulation layers 53, and together with the plating layers 56, form circuit patterns. The insulation layers 53 and the copper laminates 55 can be stacked individually on the metal core 30, or resin-coated copper (RCC) foils may be used. A resin-coated copper foil is a board in which copper plating is stacked on one side of a resin layer which acts as an insulation layer.

In order to electrically connect the upper and lower sides of the package board 50, through-holes 59 are formed that penetrate through the metal core 30, insulation layers 53, and copper laminates 55. Furthermore, plating layers 56 are formed on the inner perimeters of the through-holes 59 to connect the respective wire pads 63 with ball pads 65. Also, solder resist 61 is filled inside the through-holes 59.

The plating layers 56 are layers formed on the inner perimeters of the through-holes 59 and on the copper laminates 55. Circuit patterns are formed on the plating layers 56 by etching processes, etc. Also, with the forming of circuit patterns, wire pads 63, to which the wires 69 are connected, and ball pads 65 are formed on the plating layer 56. The wire pads 63 and ball pads 65 are connected respectively by the plating layers 56. The plating layers 56 are generally formed by plating copper or gold, which are conductive metals.

The solder resist 61 is an insulation material filled in the through-holes 59 and formed on portions of the copper laminates 55. Due to the solder resist 61, wire pads 63 are formed on the upper side of the plating layer 56 in isolation from other portions, while ball pads 65 for attaching solder balls 67 are formed on the lower side.

The circuit patterns are formed by etching, etc., on the plating layers 56 or copper laminates 55, on the upper and lower sides of the package board 50, respectively. Due to the forming of the circuit patterns, wire pads 63 are formed on the upper side of the package board 50, and ball pads 65 are formed on the lower side, respectively. The circuit patterns are insulated by the solder resist 61.

Due to the forming of the circuit patterns, the wire pads 63 are formed on the package board 50, isolated from other portions by the solder resist 61. Wires 69 connected with the chip 75 are electrically connected to the wire pads 63. The ball pads 65 are formed on the plating layers 56 positioned on the lower portion of the package board 50, and solder balls 67 are attached to the ball pads 65.

The chip 75 is mounted on a plating layer 56 of the package board 50, and is connected by the wires 69 with the wire pads 63. Further, the wire pads 63 are connected with the ball pads 65 via the plating layers 56 formed in the through-holes 59, while solder balls 67 are attached to the ball pads 65 to be electrically connected with the exterior. The wires 69, the wire pads 63, the plating layers 56 formed in the through-holes 59, and the ball pads 65 form an inner layer circuit that connects the chip 75 with the exterior. The chip 75 and the wires 69 are molded by a mold compound 77, such that they are not affected by the external environment.

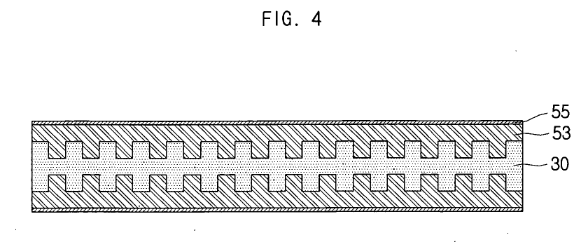

Detailed descriptions will now be provided, with reference to FIGS. 4 to 8, of a method of fabricating a package board according to an embodiment of the invention. A method of fabricating the metal core 30 will first be described.

The metal core 30 is fabricated by pressing a metal plate (not shown) having a constant thickness, through a press molding process applied on one or both sides, to form the protrusions 31. Forming the metal core 30 by press molding allows easier fabrication, and the force applied during the press molding gives the metal plate a denser structure. The metal plate used for the metal core 30 may include one of copper (Cu), aluminum (Al), titanium (Ti), zinc (Zn), and tantalum (Ta). The cross sections, heights, and intervals, etc., of the protrusions 31 may vary as necessary. Also, the protrusions 31 may be formed by etching.

Referring to FIG. 4, the insulation layers 53 and copper laminates 55 are stacked on the upper and lower sides of the metal core 30. The insulation layers 53 and copper laminates 55 may be formed using resin-coated copper (RCC) by positioning resin-coated copper foils such that the resin faces the metal core 30 and then hot-stacking.

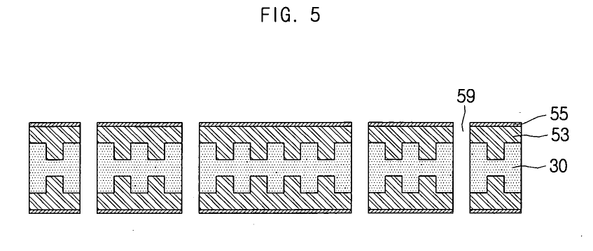

Referring to FIG. 5, through-holes 59 are formed for connecting the upper and lower sides of the metal core 30. The through-holes 59 may be formed using laser processing, such as with YAG (yttrium aluminum garnet) laser or CO₂ laser, or using mechanical drilling. YAG laser is capable of processing both the metal core 30 and the copper laminates 55.

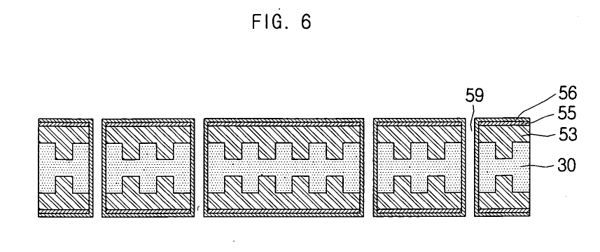

Referring to FIG. 6, plating layers 56 are formed inside the through-holes 59 and on the copper laminates 55. The plating layers 56 are formed by electroless copper plating or copper electroplating, where electroless copper plating refers to the plating performed as a preprocessing step for forming the conductive film required in copper electroplating. The plating layers 56 thus electrically connect the upper and lower sides of the package board.

After forming the plating layers 56, the circuit patterns are formed on the plating layers 56. The method of forming circuit patterns includes forming etching resist patterns (not shown) on the plating layers 56, and to form the etching resist patterns, patterns printed on an artwork film are transferred onto the plating layers 56. There are various methods for such a transfer, the most commonly used of which is to use a photosensitive dry film in transferring the circuit patterns printed on an artwork film onto a dry film by means of ultraviolet rays. LPR (liquid photo resist) may also be used instead of the dry film.

The dry film or LPR, onto which the circuit patterns have been transferred, acts as etching resist, and when the board is immersed in etching liquid, the plating layers are removed in regions where the etching resist patterns have not been formed, so that particular circuit patterns are formed. After forming the circuit patterns, the exterior appearance of the circuit is inspected by a method such as AOI (automatic optical inspection), etc., to ensure that the circuits have been formed properly, and a surface processing is performed, such as black oxide processing. AOI is a method for automatically inspecting the exterior appearance of a board, which inspects the exterior of a board by means of pattern recognition technology using an image sensor and computer. The image sensor reads the pattern information of the subject circuit, after which it is compared with reference data to determine the existence of defects. Black oxide processing is a process for increasing adhesion and heat resistance before attaching an inner layer, on which the wiring patterns are formed, with an outer layer.

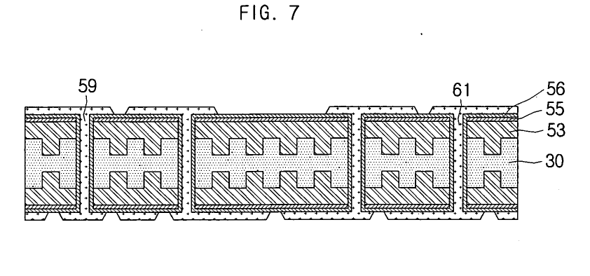

Referring to FIG. 7, solder resist 61 is applied inside the through-holes 59 and on the plating layers 56. The solder resist 61 not only protects the plating layers 56 formed on the inner perimeters of the through-holes 59, but also forms the wire pads 63 and ball pads 65.

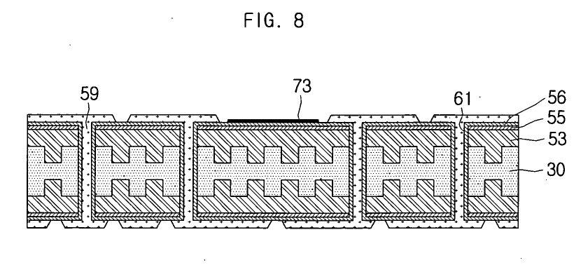

Referring to FIG. 8, a peelable coating 73 is attached on the portion where the chip 75 is to be placed, as illustrated in FIG. 3. With the peelable coating 73 attached, gold plating is performed on the wire pads 63 and ball pads 65. The reason for using the peelable coating 73 is because the chip 75 may not be firmly attached onto the upper portion of the plating layer 56 if the plating process is performed on the portion where the chip 75 is to be placed. As illustrated in FIG. 3, the chip 75 is mounted after the peelable coating 73 is removed, the chip 75 and the wire pads 63 are connected with the wires 69, and then molding is performed with a mold compound 77 for protecting the chip 75. Afterwards, solder balls 67 are formed on the ball pads 65, to complete a ball grid array (hereafter referred to as “BGA”) package.

While this embodiment used a BGA package as an example, the present invention is not thus limited, and may be applied to any type of board which can utilize the metal core. For example, the metal core may also be used in a flip chip package.

According to the invention comprised as set forth above, a metal core, a package board having the metal core, and a fabricating method thereof may be provided, which provide superior heat releasing properties and superior mechanical properties with respect to warpage.

Also, a metal core, a package board having the metal core, and a fabricating method thereof may be provided, which allow easy adhesion to an insulation layer.

While the present invention has been described with reference to particular embodiments, it is to be appreciated that various changes and modifications may be made by those skilled in the art without departing from the spirit and scope of the present invention, as defined by the appended claims and their equivalents.

What is claimed is:

1. A metal core used in a circuit board, the metal core comprising:
a plurality of protrusions formed in a lengthwise direction on a surface thereof.

2. The metal core of claim 1, wherein the protrusions are formed on both sides of the metal core.

3. The metal core of claim 1, including any one of copper (Cu), aluminum (Al), titanium (Ti), zinc (Zn), and tantalum (Ta).

4. A package board comprising:
a metal core having a plurality of protrusions formed in a lengthwise direction on a surface thereof;
an insulation layer stacked on the metal core; and
an inner layer circuit formed on the insulation layer for signal connection between a chip and the exterior.

5. The package board of claim 4, wherein the insulation layer comprises a resin coated on a resin-coated copper foil.

6. The package board of claim 4, wherein the protrusions are formed on both sides of the metal core.

7. The package board of claim 4, wherein the metal core is formed including any one of copper (Cu), aluminum (Al), titanium (Ti), zinc (Zn), and tantalum (Ta).

8. A method of fabricating a package board, the method comprising:
(a) processing at least one surface of a metal plate to provide a metal core having protrusions formed in a lengthwise direction;
(b) stacking at least one insulation layer on the metal core; and
(c) forming an inner layer circuit and mounting a chip.

9. The method of claim 8, wherein in the operation (a) of processing at least one surface of a metal plate to provide a metal core having protrusions formed in a lengthwise direction, the metal core is formed by press processing.

10. The method of claim 8, wherein the operation (a) of processing at least one surface of a metal plate to provide a metal core having protrusions formed in a lengthwise direction comprises forming the protrusions on both sides of the metal plate.

11. The method of claim 8, wherein in the operation (a) of processing at least one surface of a metal plate to provide a metal core having protrusions formed in a lengthwise direction, the metal plate includes any one of copper (Cu), aluminum (Al), titanium (Ti), zinc (Zn), and tantalum (Ta).

12. The method of claim 8, wherein the operation (b) of stacking at least one insulation layer on the metal core comprises stacking a resin-coated copper foil on the metal core.
